(19) United States
(12) Patent Application Publication
(10) Pub. No.: US 2026/0357418 A1
(43) Pub. Date: Nov. 12, 2026

(54) COMPOSITIONS COMPRISING ALUMINUM AND/OR GALLIUM OXIDE ON A MISCUT SUBSTRATE, AND METHODS OF MAKING AND USE THEREOF

(71) Applicant: Ohio State Innovation Foundation, Columbus, OH (US)

(72) Inventors: Hongping ZHAO, Dublin, OH (US); A F M Anhar Uddin BHUIYAN, Lowell, MA (US); Lingyu MENG, Columbus, OH (US)

(21) Appl. No.: 19/136,193

(22) PCT Filed: Dec. 11, 2023
(86) PCT No.: PCT/US2023/083338

§ 371 Date: Jun. 5, 2025

Related U.S. Application Data
(60) Provisional application No. 63/431,778, filed on Dec. 12, 2022.

(51) Int. Cl. C23C 16/40; H10D 62/80

(52) U.S. Cl. CPC C23C 16/40; H10D 62/875

(57) ABSTRACT

Disclosed herein are compositions, methods, and devices. For example, disclosed herein are compositions comprising aluminum and/or gallium oxide on a miscut substrate, and methods of making and use thereof. For example, disclosed herein is a composition comprising a first layer disposed on a substrate, wherein the first layer comprises β—(Al_{z}Ga_{1-z})₂O₃ where x is from 0 to 1, and the substrate comprises β—(Al_{z}Ga_{1-z})₂O₃ having a miscut angle of 5° or less, where z is from 0 to 1.

### CROSS-REFERENCE TO RELATED APPLICATIONS

This application claims the benefit of priority to U.S. Provisional Application No. 63/431,778 filed Dec. 12, 2022, which is hereby incorporated herein by reference in its entirety.

### STATEMENT OF GOVERNMENT SUPPORT

This invention was made with government support under grant/contract number 2019753 awarded by the National Science Foundation. The government has certain rights in the invention.

### BACKGROUND

Compositions and devices with improved properties are needed. The compositions, methods, and devices discussed herein addresses these and other needs.

### SUMMARY

In accordance with the purposes of the disclosed compositions, methods, and devices as embodied and broadly described herein, the disclosed subject matter relates to compositions and devices and methods of making and use thereof. For example, disclosed herein are compositions comprising aluminum and/or gallium oxide on a miscut substrate, and methods of making and use thereof.

For example, disclosed herein is a composition comprising a first layer disposed on a substrate, wherein the first layer comprises β—(AlₓGa₁₋ₓ)₂O₃ where x is from 0 to 1, and the substrate comprises β—(Al_{z}Ga_{1-z})₂O₃ having a miscut angle of 5° or less, where z is from 0 to 1.

In some examples, the miscut angle is 2° or less, 1.5° or less, or 1.25° or less.

In some examples, the first layer has an average thickness of from 0.1 μm to 1000 μm, or from 1 μm to 1000 μm. In some examples, the first layer has an average thickness of 1 μm or more, 5 μm or more, 10 μm or more, 50 μm or more, or 100 μm or more.

In some examples, the first layer has a surface with an RMS roughness of 50 nm or less, 25 nm or less, 10 nm or less, 5 nm or less, 2.5 nm or less, or 1 nm or less as measured by AFM.

In some examples, the first layer has a reflection rocking curve with a full width at half maximum (FWHM) of 500 arcsec or less, 200 arcsec or less, 150 arcsec or less, 125 arcsec or less, or 100 arcsec or less as measured x-ray diffraction (XRD). In some examples, the first layer has an (020) reflection rocking curve with a full width at half maximum (FWHM) of 500 arcsec or less, 200 arcsec or less, 150 arcsec or less, 125 arcsec or less, or 100 arcsec or less as measured x-ray diffraction (XRD).

In some examples, the first layer further comprises a dopant. In some examples, the dopant comprises an N-type dopant, such as Si.

In some examples, x is 0.

In some examples, z is 0.

In some examples, z is 0 and x is 0.3 or less, 0.1 or less, or 0.03 or less.

In some examples, the first layer and the substrate are substantially the same composition.

In some examples, the substrate comprising β—(Al_{z}Ga_{1-z})₂O₃ has a crystal orientation of (010), (100), (001), or (−201). In some examples, the substrate comprising β—(Al_{z}Ga_{1-z})₂O₃ has a crystal orientation of (010).

In some examples, x and z are both 0, such that the composition comprises a β—Ga₂O₃ layer disposed on a β—Ga₂O₃ miscut substrate.

In some examples, the substrate comprises β—(AlₓGa₁₋ₓ)₂O₃, such that the composition comprises a β—(AlₓGa₁₋ₓ)₂O₃ layer disposed on a β—(AlₓGa₁₋ₓ)₂O₃ miscut substrate.

In some examples, x and z are both 0, such that the composition comprises a β—Ga₂O₃ layer disposed on a (010) β—Ga₂O₃ miscut substrate.

In some examples, the substrate comprises β—(AlₓGa₁₋ₓ)₂O₃, such that the composition comprises a β—(AlₓGa₁₋ₓ)₂O₃ layer disposed on a (010) β—(AlₓGa₁₋ₓ)₂O₃ miscut substrate.

In some examples, the composition further comprises a second layer disposed on the first layer opposite the substrate, wherein the second layer comprises β—(Al_{y}Ga_{1-y})₂O₃ where y is from 0 to 1, a doped material (e.g., a p-type material), or a combination thereof. In some examples, the composition of the second layer varies, such that the second layer has a compositional gradient, such as with thickness. In some examples, the second layer comprises β—(Al_{y}Ga_{1-y})₂O₃ and the value of y varies across the layer, such as with thickness.

Also disclosed herein are methods of making any of the compositions disclosed herein. For example, the methods comprise contacting a first precursor and a second precursor at a first temperature and a first pressure in the presence of the substrate, wherein the first precursor comprises gallium and/or aluminum and the second precursor comprises oxygen, to thereby react the first precursor and the second precursor to deposit the first layer on the substrate.

In some examples, the method comprises metal organic chemical vapor deposition (MOCVD), molecular-beam epitaxy (MBE), hydride vapor phase epitaxy (HVPE), pulsed laser deposition (PLD), low pressure chemical vapor deposition (LPCVD), mist-CVD, or a combination thereof. In some examples, the method comprises metal organic chemical vapor deposition (MOCVD).

In some examples, the first precursor and/or the second precursor independently comprise(s) a fluid, such as a gas.

In some examples, the first precursor comprises gallium. In some examples, the first precursor comprises trimethylgallium (TMGa), triethylgallium (TEGa), pure Ga or Ga-containing precursors, or a combination thereof. In some examples, the first precursor comprises trimethylgallium (TMGa), triethylgallium (TEGa), or a combination thereof. In some examples, the first precursor comprises trimethylgallium (TMGa).

In some examples, the first precursor comprises aluminum. In some examples, the first precursor comprises trimethylaluminum (TMAl), triethylaluminum (TEAl), or a combination thereof.

In some examples, the first precursor comprises trimethylgallium (TMGa), triethylgallium (TEGa), trimethylaluminum (TMAl), triethylaluminum (TEAl), or a combination thereof.

In some examples, the first precursor comprises gallium and aluminum. In some examples, the first precursor comprises a gallium containing precursor and an aluminum containing precursor. In some examples, the first precursor comprises a gallium containing precursor and an aluminum containing precursor, the gallium containing precursor comprising trimethylgallium (TMGa), triethylgallium (TEGa), or a combination thereof, and the aluminum containing precursor comprising trimethylaluminum (TMAl), triethylaluminum (TEAl).

In some examples, the first precursor is provided at a flow rate of from 0.01 to 1000 μmole/minute, such as from 1 to 250 μmole/minute.

In some examples, the second precursor comprises O₂ or an oxygen-containing precursor, such as H₂O. In some examples, the second precursor comprises O₂.

In some examples, in the first temperature is from 600 °C to 1100 °C, such as from 650 °C to 1000 °C.

In some examples, the method produces the first layer at a growth rate of 1 μm/hour or more, 3 μm/hour or more, 5.5 μm/hour or more, or 10 μm/hour or more.

In some examples, the first pressure is from 5 to 600 torr.

In some examples, the method further comprises introducing a third precursor comprising a dopant, such that the composition further comprises the dopant. In some examples, the third precursor is provided as a fluid, such as a gas. In some examples, the third precursor comprises a Si containing precursor, a Ge containing precursor, a Sn containing precursor, a Mg containing precursor, or a combination thereof. In some examples, the third precursor comprises silane (SiH₄), germane (GeH₄), disilane (Si₂H₆), bis(cyclopentadienyl)magnesium (Cp₂Mg), bis(methylcyclopentadienyl)magnesium ((MeCp)₂Mg), or a combination thereof. In some examples, the third precursor comprises silane (SiH₄).

In some examples, the first precursor, the second precursor, the third precursor (when present), or a combination thereof are independently provided with a carrier gas. In some examples, the carrier gas comprises argon, helium, H₂, N₂, and the like, or combinations thereof.

In some examples, the method further comprises depositing the second layer on the first layer.

Also disclosed herein are compositions made by any of the methods disclosed herein.

Also disclosed herein are devices comprising any of the compositions disclosed herein. In some examples, the device comprises a vertical power device. In some examples, the device comprises a vertical Schottky barrier diode such as a vertical trench Schottky barrier diode, a PN heterojunction power diode, or a combination thereof. In some examples, the device comprises an optical device, an electronic device, an optoelectronic device, or a combination thereof.

Also disclosed herein are methods of use of any of the compositions disclosed herein.

Additional advantages of the disclosed compositions, devices, and methods will be set forth in part in the description which follows, and in part will be obvious from the description. The advantages of the disclosed compositions, devices, and methods will be realized and attained by means of the elements and combinations particularly pointed out in the appended claims. It is to be understood that both the foregoing general description and the following detailed description are exemplary and explanatory only and are not restrictive of the disclosed devices and methods, as claimed.

The details of one or more embodiments of the invention are set forth in the accompanying drawings and the description below. Other features, objects, and advantages of the invention will be apparent from the description and drawings, and from the claims.

### BRIEF DESCRIPTION OF THE FIGURES

The accompanying figures, which are incorporated in and constitute a part of this specification, illustrate several aspects of the disclosure, and together with the description, serve to explain the principles of the disclosure.

FIG. 1A-FIG. 1D. Optical macroscopic surface morphology of β—GazO₃ films grown on (010) β—Ga₂O₃ substrates (FIG. 1A, FIG. 1C) without and (FIG. 1B, FIG. 1D) with miscuts; showing less dense bumps on the film surfaces grown on offcut (miscut) substrates. All the films are grown with same growth rate of 5.5 μm/hr with different thicknesses of (FIG. 1A, FIG. 1B) 5.5 μm and (FIG. 1C, FIG. 1D) 11 μm.

FIG. 2A-FIG. 2D. Surface SEM images of β—Ga₂O₃ films grown on (010) β—Ga₂O₃ substrates (FIG. 2A, FIG. 2C) without and (FIG. 2B, FIG. 2D) with miscuts; showing less dense bumps on the film surfaces grown on offcut (miscut) substrates. All the films are grown with same growth rate of 5.5 μm/hr with different thicknesses of (FIG. 2A, FIG. 2B) 5.5 μm and (FIG. 2C, FIG. 2D) 11 μm.

FIG. 3A-FIG. 3B. Surface AFM images (scan area: 30 μm×30 μm) of β—Ga₂O₃ films grown on (010) β—Ga₂O₃ substrates (FIG. 3A) without and (FIG. 3B) with miscuts, showing significantly improved surface morphology with lower RMS roughness for the films grown on offcut (miscut) substrates. The films are grown with growth rate of 5.5 μm/hr with thicknesses of 5.5 μm.

FIG. 4A-FIG. 4B. XRD Rocking curve full width at half maximum (FWHMs) from (020) reflection of β—Ga₂O₃ films (5.5 μm thick) grown on (FIG. 4A) on-axis and (FIG. 4B) off-axis (miscut) (010) β—Ga₂O₃ substrates, showing lower FWHM for the films grown on offcut (miscut) substrates. The films are grown with growth rate of 5.5 μm/hr.

FIG. 5A-FIG. 5B. Schematic illustrations of the growth mechanism of (010) β—Ga₂O₃ films on (010) β—Ga₂O₃ substrates: (FIG. 5A) typical 3D island mode growth processes on (010) on-axis β—Ga₂O₃ substrates including (1) the absorption and diffusion of incoming adatoms, (2) formation of 3D islands by the encounter of Ga adatoms due to the lack of energetically favorable lattice sites, such as surface steps or kinks, (3) incorporation of an adatom into an existing island and (FIG. 5B) step flow growth processes on (010) β—Ga₂O₃ substrates with miscuts, including (1) absorption, diffusion, and fast adherence of incoming Ga adatoms on the growth surface and (2) incorporation of Ga adatoms at the surface edges.

FIG. 6A-FIG. 6B. Optical macroscopic surface morphology of 5.5 μm thick β—(AlₓGa₁₋ₓ)₂O₃ films grown on (010) β—Ga₂O₃ substrates (FIG. 6A) without (on-axis) and (FIG. 6B) with (off-axis) miscuts; showing less dense bumps on the film surfaces grown on offcut (miscut) substrates. The films are grown with same growth rate of 5.5 μm/hr.

FIG. 7A-FIG. 7B. Surface SEM images of 5.5 μm thick β—(AlₓGa₁₋ₓ)₂O₃ films grown on (010) β—Ga₂O₃ substrates (FIG. 7A) without (on-axis) and (FIG. 7B) with (off-axis) miscuts; showing less dense bumps on the film surfaces grown on offcut (miscut) substrates. The films are grown with same growth rate of 5.5 μm/hr.

FIG. 8A-FIG. 8B. XRD ω-2θ scan profiles of β—(AlₓGa₁₋ₓ)₂O₃ films grown on (010) β—Ga₂O₃ substrates (FIG. 8A) with (off-axis) and (FIG. 8B) without (on-axis) miscuts; showing same Al incorporation of 20%. The targeted film thicknesses were 60 nm.

FIG. 9. Schematic of a cross sectional view of a β—Ga₂O₃ Schottky barrier diode structure using thick β—Ga₂O₃ drift layer grown on (010) β—Ga₂O₃ substrates with miscuts (off-axis) in accordance with the present invention.

FIG. 10. A general design of β—Ga₂O₃ Schottky barrier diode with a graded Al content β—(Al_{y}Ga_{1-y})₂O₃ cap layer grown on top of thick β—Ga₂O₃ drift layer grown on (010) β—Ga₂O₃ substrates with miscuts (off-axis) in accordance with the present invention for boosting device performance with high power figure-of-merit (P-FOM).

FIG. 11. A general design of β—Ga₂O₃ PN heterojunction power diodes grown using thick β—Ga₂O₃ drift layer on (010) β—Ga₂O₃ substrates with miscuts (off-axis) in accordance with the present invention.

FIG. 12. Schematic of a cross sectional view of a β—(AlₓGa₁₋ₓ)₂O₃ Schottky barrier diode structure grown using thick β—(AlₓGa₁₋ₓ)₂O₃ drift layer on lattice-matched β—(AlₓGa₁₋ₓ)₂O₃ substrate with miscuts (off-axis) in accordance with the present invention.

FIG. 13. A general design of β—(AlₓGa₁₋ₓ)₂O₃ Schottky barrier diode with a graded Al content β—(Al_{y}Ga_{1-y})₂O₃ cap layer grown on top of thick low-Al content β—(AlₓGa₁₋ₓ)₂O₃ drift layer on lattice-matched β—(AlₓGa₁₋ₓ)₂O₃ substrate with miscuts in accordance with the present invention for enhancing device performance with high power figure-of-merit (P-FOM).

FIG. 14. A general design of β—(AlₓGa₁₋ₓ)₂O₃ PN heterojunction power diodes grown using thick β—(AlₓGa₁₋ₓ)₂O₃ as n-type drift layer on lattice-matched off-axis β—(AlₓGa₁₋ₓ)₂O₃ substrate in accordance with the present invention.

### DETAILED DESCRIPTION

The compositions, methods, and devices described herein may be understood more readily by reference to the following detailed description of specific aspects of the disclosed subject matter and the Examples included therein.

Before the present compositions, methods, and devices are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

In this specification and in the claims that follow, reference will be made to a number of terms, which shall be defined to have the following meanings.

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Values can be expressed herein as an “average” value. “Average” generally refers to the statistical mean value.

By “substantially” is meant within 5%, e.g., within 4%, 3%, 2%, or 1%. “Exemplary” means “an example of” and is not intended to convey an indication of a preferred or ideal embodiment. “Such as” is not used in a restrictive sense, but for explanatory purposes.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

References in the specification and concluding claims to parts by weight of a particular element or component in a composition denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent (wt. %) of a component, unless specifically stated to the contrary, is based on the total weight of the formulation or composition in which the component is included.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

### Compositions, Methods, and Devices

Disclosed herein are compositions comprising a first layer disposed on a substrate. In some examples, the first layer is disposed on and in physical contact with the substrate. The first layer comprises β—(AlₓGa₁₋ₓ)₂O₃ and the substrate comprises β—(Al_{z}Ga_{1-z})₂O₃ having a miscut angle of 5° or less.

The substrate comprising β—(Al_{z}Ga_{1-z})₂O₃ can have any suitable crystal orientation, such as, for example (010), (100), (001), (−201), etc. In some examples, the substrate comprising β—(Al_{z}Ga_{1-z})₂O₃ has a crystal orientation of (010), such that the substrate comprises (010) β—(Al_{z}Ga_{1-z})₂O₃ having a miscut angle.

The miscut angle of the substrate is 5° or less (e.g., 4.75° or less, 4.5° or less, 4.25° or less, 4° or less, 3.75° or less, 3.5° or less, 3.25° or less, 3° or less, 2.75° or less, 2.5° or less, 2.25° or less, 2° or less, 1.75° or less, 1.5° or less, 1.25° or less, 1° or less, 0.9° or less, 0.8° or less, 0.7° or less, 0.6° or less, 0.5° or less, 0.45° or less, 0.4° or less, 0.35° or less, 0.3° or less, 0.25° or less, 0.2° or less, 0.15° or less, or 0.1° or less). In some examples, the miscut angle can be greater than 0°(e.g., 0.1° or more, 0.15° or more, 0.2° or more, 0.25° or more, 0.3° or more, 0.35° or more, 0.4° or more, 0.45° or more, 0.5° or more, 0.6° or more, 0.7° or more, 0.8° or more, 0.9° or more, 1° or more, 1.25° or more, 1.5° or more, 1.75° or more, 2° or more, 2.25° or more, 2.5° or more, 2.75° or more, 3° or more, 3.25° or more, 3.5° or more, 3.75° or more, 4° or more, 4.25° or more, 4.5° or more, or 4.75° or more). The miscut angle can range from any of the minimum values described above to any of the maximum values described above. For example, the miscut angle can be from greater than 0° to 5°(e.g., from greater than 0° to 2.5°, from 2.5° to 5°, from greater than 0° to 1°, from 1° to 2°, from 2° to 3°, from 3° to 4°, from 4° to 5°, from greater than 0° to 4°, from greater than 0° to 3°, from greater than 0° to 2°, from greater than 0° to 1.5°, from greater than 0° to 1.25°, from 0.1° to 4.5°, or from 0.5° to 4°).

The first layer comprises β—(AlₓGa₁₋ₓ)₂O₃ where x is from 0 to 1. In some examples, x is 0 or more (e.g., 0.01 or more, 0.02 or more, 0.03 or more, 0.04 or more, 0.05 or more, 0.06 or more, 0.07 or more, 0.08 or more, 0.09 or more, 0.1 or more, 0.15 or more, 0.2 or more, 0.25 or more, 0.3 or more, 0.35 or more, 0.4 or more, 0.45 or more, 0.5 or more, 0.6 or more, 0.7 or more, 0.8 or more, or 0.9 or more). In some examples, x is 1 or less (e.g., 0.9 or less, 0.8 or less, 0.7 or less, 0.6 or less, 0.5 or less, 0.45 or less, 0.4 or less, 0.35 or less, 0.3 or less, 0.25 or less, 0.2 or less, 0.15 or less, 0.1 or less, 0.09 or less, 0.08 or less, 0.07 or less, 0.06 or less, 0.05 or less, 0.04 or less, 0.03 or less, 0.02 or less, or 0.01 or less). The value of x can range from any of the minimum values described above to any of the maximum values described above. For example, x can be from 0 to 1 (e.g., from 0 to 0.5, from 0.5 to 1, from 0 to 0.2, from 0.2 to 0.4, from 0.4 to 0.6, from 0.6 to 0.8, from 0.8 to 1, from 0 to 0.9, from 0 to 0.8, from 0 to 0.7, from 0 to 0.6, from 0 to 0.5, from 0 to 0.4, from 0 to 0.3, from 0 to 0.2, from 0 to 0.1, from 0 to 0.05, from 0 to 0.04, from 0 to 0.03, from 0 to 0.02, from 0.01 to 0.9, or from 0.1 to 0.8). In some examples, x is 0.

The substrate comprises β—(Al_{z}Ga_{1-z})₂O₃ having a miscut angle of 5° or less, where z is from 0 to 1. In some examples, the substrate comprises (010) β—(Al_{z}Ga_{1-z})₂O₃ having a miscut angle of 5° or less, where z is from 0 to 1. In some examples, z is 0 or more (e.g., 0.01 or more, 0.02 or more, 0.03 or more, 0.04 or more, 0.05 or more, 0.06 or more, 0.07 or more, 0.08 or more, 0.09 or more, 0.1 or more, 0.15 or more, 0.2 or more, 0.25 or more, 0.3 or more, 0.35 or more, 0.4 or more, 0.45 or more, 0.5 or more, 0.6 or more, 0.7 or more, 0.8 or more, or 0.9 or more). In some examples, z is 1 or less (e.g., 0.9 or less, 0.8 or less, 0.7 or less, 0.6 or less, 0.5 or less, 0.45 or less, 0.4 or less, 0.35 or less, 0.3 or less, 0.25 or less, 0.2 or less, 0.15 or less, 0.1 or less, 0.09 or less, 0.08 or less, 0.07 or less, 0.06 or less, 0.05 or less, 0.04 or less, 0.03 or less, 0.02 or less, or 0.01 or less). The value of z can range from any of the minimum values described above to any of the maximum values described above. For example, z can be from 0 to 1 (e.g., from 0 to 0.5, from 0.5 to 1, from 0 to 0.2, from 0.2 to 0.4, from 0.4 to 0.6, from 0.6 to 0.8, from 0.8 to 1, from 0 to 0.9, from 0 to 0.8, from 0 to 0.7, from 0 to 0.6, from 0 to 0.5, from 0 to 0.4, from 0 to 0.3, from 0 to 0.2, from 0 to 0.1, from 0 to 0.05, from 0 to 0.04, from 0 to 0.03, from 0 to 0.02, from 0.01 to 0.9, or from 0.1 to 0.8). In some examples, z is 0.

In some examples, z is 0 and x is 0.3 or less (e.g., 0.25 or less, 0.2 or less, 0.15 or less, 0.1 or less, 0.09 or less, 0.08 or less, 0.07 or less, 0.06 or less, 0.05 or less, 0.04 or less, 0.03 or less, 0.02 or less, or 0.01 or less).

In some examples, the first layer and the substrate are substantially the same composition.

In some examples, x and z are both 0, such that the composition comprises a β—Ga₂O₃ layer disposed on a β—Ga₂O₃ miscut substrate. In some examples, x and z are both 0, such that the composition comprises a β—Ga₂O₃ layer disposed on a (010) β—Ga₂O₃ miscut substrate.

In some examples, the substrate comprises β—(AlₓGa₁₋ₓ)₂O₃, such that the composition comprises a β—(AlₓGa₁₋ₓ)₂O₃ layer disposed on a β—(AlₓGa₁₋ₓ)₂O₃ miscut substrate. In some examples, the substrate comprises β—(AlₓGa₁₋ₓ)₂O₃, such that the composition comprises a β—(AlₓGa₁₋ₓ)₂O₃ layer disposed on a (010) ⊕—(AlₓGa₁₋ₓ)₂O₃ miscut substrate.

The first layer can, for example, have an average thickness of 0.1 μm or more (e.g., 0.25 μm or more, 0.5 μm or more, 0.75 μm or more, 1 μm or more, 1.5 μm or more, 2 μm or more, 2.5 μm or more, 3 μm or more, 4 μm or more, 5 μm or more, 10 μm or more, 15 μm or more, 20 μm or more, 25 μm or more, 30 μm or more, 35 μm or more, 40 μm or more, 45 μm or more, 50 μm or more, 60 μm or more, 70 μm or more, 80 μm or more, 90 μm or more, 100 μm or more, 125 μm or more, 150 μm or more, 175 μm or more, 200 μm or more, 225 μm or more, 250 μm or more, 300 μm or more, 350 μm or more, 400 μm or more, 450 μm or more, 500 μm or more, 600 μm or more, 700 μm or more, 800 μm or more, or 900 μm or more). In some examples, the first layer can have an average thickness of 1000 μm or less (e.g., 900 μm or less, 800 μm or less, 700 μm or less, 600 μm or less, 500 μm or less, 450 μm or less, 400 μm or less, 350 μm or less, 300 μm or less, 250 μm or less, 225 μm or less, 200 μm or less, 175 μm or less, 150 μm or less, 125 μm or less, 100 μm or less, 90 μm or less, 80 μm or less, 70 μm or less, 60 μm or less, 50 μm or less, 45 μm or less, 40 μm or less, 35 μm or less, 30 μm or less, 25 μm or less, 20 μm or less, 15 μm or less, 10 μm or less, 5 μm or less, 2.5 μm or less, or 1 μm or less). The average thickness of the first layer can range from any of the minimum values described above to any of the maximum values described above. For example, the first layer can have an average thickness of from 0.1 μm to 1000 μm (e.g., from 0.1 μm to 500 μm, from 500 μm to 1000 μm, from 0.1 to 200 μm, from 200 μm to 400 μm, from 400 μm to 600 μm, from 600 μm to 800 μm, from 800 μm to 1000 μm, from 1 μm to 1000 μm, from 5 μm to 1000 μm, from 10 μm to 1000 μm, from 25 μm to 1000 μm, from 50 μm to 1000 μm, from 100 μm to 1000 μm, from 200 μm to 1000 μm, from 300 μm to 1000 μm, from 400 μm to 1000 μm, from 600 μm to 1000 μm, from 700 μm to 1000 μm, from 1 to 500 μm, from 1 to 200 μm, from 10 μm to 900 μm, from 25 μm to 800 μm, from 50 μm to 700 μm, or from 100 μm to 500 μm).

In some examples, the first layer has a surface with an RMS roughness of 50 nm or less (e.g., 45 nm or less, 40 nm or less, 35 nm or less, 30 nm or less, 25 nm or less, 20 nm or less, 15 nm or less, 10 nm or less, 9 nm or less, 8 nm or less, 7 nm or less, 6 nm or less, 5 nm or less, 4.5 nm or less, 4 nm or less, 3.5 nm or less, 3 nm or less, 2.5 nm or less, 2 nm or less, 1.5 nm or less, 1 nm or less, or 0.5 nm or less) as measured by AFM.

In some examples, the first layer has a reflection rocking curve with a full width at half maximum (FWHM) of 500 arcsec or less (e.g., 475 arcsec or less, 450 arcsec or less, 425 arcsec or less, 400 arcsec or less, 375 arcsec or less, 350 arcsec or less, 325 arcsec or less, 300 arcsec or less, 275 arcsec or less, 250 arcsec or less, 225 arcsec or less, 200 arcsec or less, 175 arcsec or less, 150 arcsec or less, 125 arcsec or less, 100 arcsec or less, 75 arcsec or less, 50 arcsec or less, 25 arcsec or less, or 10 arcsec or less) as measured x-ray diffraction (XRD). The rocking curve can be for any suitable crystal orientation, such as, for example (020), (010), (001), (100), or (−201).

In some examples, the first layer has an (020) reflection rocking curve with a full width at half maximum (FWHM) of 500 arcsec or less (e.g., 475 arcsec or less, 450 arcsec or less, 425 arcsec or less, 400 arcsec or less, 375 arcsec or less, 350 arcsec or less, 325 arcsec or less, 300 arcsec or less, 275 arcsec or less, 250 arcsec or less, 225 arcsec or less, 200 arcsec or less, 175 arcsec or less, 150 arcsec or less, 125 arcsec or less, 100 arcsec or less, 75 arcsec or less, 50 arcsec or less, 25 arcsec or less, or 10 arcsec or less) as measured x-ray diffraction (XRD).

In some examples, the first layer further comprises a dopant. In some examples, the dopant comprises an N-type dopant, such as Si.

In some examples, the composition further comprises a second layer disposed on the first layer opposite the substrate, wherein the second layer comprises β—(Al_{y}Ga_{1-y})₂O₃ where y is from 0 to 1, a doped material (e.g., a p-type material), or a combination thereof.

In some examples, the second layer comprises β—(Al_{y}Ga_{1-y})₂O₃ where y is from 0 to 1. In some examples, y is 0 or more (e.g., 0.01 or more, 0.02 or more, 0.03 or more, 0.04 or more, 0.05 or more, 0.06 or more, 0.07 or more, 0.08 or more, 0.09 or more, 0.1 or more, 0.15 or more, 0.2 or more, 0.25 or more, 0.3 or more, 0.35 or more, 0.4 or more, 0.45 or more, 0.5 or more, 0.6 or more, 0.7 or more, 0.8 or more, or 0.9 or more). In some examples, y is 1 or less (e.g., 0.9 or less, 0.8 or less, 0.7 or less, 0.6 or less, 0.5 or less, 0.45 or less, 0.4 or less, 0.35 or less, 0.3 or less, 0.25 or less, 0.2 or less, 0.15 or less, 0.1 or less, 0.09 or less, 0.08 or less, 0.07 or less, 0.06 or less, 0.05 or less, 0.04 or less, 0.03 or less, 0.02 or less, or 0.01 or less). The value of y can range from any of the minimum values described above to any of the maximum values described above. For example, y can be from 0 to 1 (e.g., from 0 to 0.5, from 0.5 to 1, from 0 to 0.2, from 0.2 to 0.4, from 0.4 to 0.6, from 0.6 to 0.8, from 0.8 to 1, from 0 to 0.9, from 0 to 0.8, from 0 to 0.7, from 0 to 0.6, from 0 to 0.5, from 0 to 0.4, from 0 to 0.3, from 0 to 0.2, from 0 to 0.1, from 0 to 0.05, from 0 to 0.04, from 0 to 0.03, from 0 to 0.02, from 0.01 to 0.9, or from 0.1 to 0.8).

In some examples, the composition of the second layer varies, such that the second layer has a compositional gradient, such as with thickness. The compositional gradient can, for example, be a linear gradient, a stepped gradient, an exponential gradient, a logarithmic gradient, etc., or a combination thereof. In some examples, the second layer comprises β—(Al_{y}Ga_{1-y})₂O₃ and the value of y varies across the layer, such as with thickness.

Also disclosed herein are methods of making any of the compositions disclosed herein. The methods can comprise, for example, contacting a first precursor and a second precursor at a first temperature and a first pressure in the presence of the substrate, wherein the first precursor comprises gallium and/or aluminum and the second precursor comprises oxygen, to thereby react the first precursor and the second precursor to deposit the first layer on the substrate. In some examples, the method comprises metal organic chemical vapor deposition (MOCVD), molecular-beam epitaxy (MBE), hydride vapor phase epitaxy (HVPE), pulsed laser deposition (PLD), low pressure chemical vapor deposition (LPCVD), mist-CVD, or a combination thereof. In some examples, the method comprises metal organic chemical vapor deposition (MOCVD).

In some examples, the first precursor and/or the second precursor independently comprise(s) a fluid, such as a gas.

In some examples, the first precursor comprises gallium. In some examples, the first precursor comprises trimethylgallium (TMGa), triethylgallium (TEGa), pure Ga or Ga-containing precursors, or a combination thereof. In some examples, the first precursor comprises trimethylgallium (TMGa), triethylgallium (TEGa), or a combination thereof. In some examples, the first precursor comprises trimethylgallium (TMGa).

In some examples, the first precursor comprises aluminum. In some examples, the first precursor comprises trimethylaluminum (TMAl), triethylaluminum (TEAl), pure Al or Al-containing precursors, or a combination thereof. In some examples, the first precursor comprises trimethylaluminum (TMAl), triethylaluminum (TEAl), or a combination thereof.

In some examples, the first precursor comprises trimethylgallium (TMGa), triethylgallium (TEGa), trimethylaluminum (TMAl), triethylaluminum (TEAl), or a combination thereof.

In some examples, the first precursor comprises gallium and aluminum. In some examples, the first precursor comprises a gallium containing precursor and an aluminum containing precursor. In some examples, the first precursor comprises a gallium containing precursor and an aluminum containing precursor, the gallium containing precursor comprising trimethylgallium (TMGa), triethylgallium (TEGa), or a combination thereof, and the aluminum containing precursor comprising trimethylaluminum (TMAl), triethylaluminum (TEAl).

In some examples, the first precursor is provided at a flow rate of 0.01 μmole/minute or more (e.g., 0.025 μmol/min or more, 0.05 μmol/min or more, 0.075 μmol/min or more, 0.1 μmol/min or more, 0.25 μmol/min or more, 0.5 μmol/min or more, 0.75 μmol/min or more, 1 μmol/min or more, 1.5 μmol/min or more, 2 μmol/min or more, 2.5 μmol/min or more, 3 μmol/min or more, 4 μmol/min or more, 5 μmol/min or more, 6 μmol/min or more, 7 μmol/min or more, 8 μmol/min or more, 9 μmol/min or more, 10 μmol/min or more, 15 μmol/min or more, 20 μmol/min or more, 25 μmol/min or more, 30 μmol/min or more, 35 μmol/min or more, 40 μmol/min or more, 45 μmol/min or more, 50 μmol/min or more, 55 μmol/min or more, 60 μmol/min or more, 65 μmol/min or more, 70 μmol/min or more, 75 μmol/min or more, 80 μmol/min or more, 85 μmol/min or more, 90 μmol/min or more, 95 μmol/min or more, 100 μmol/min or more, 105 μmol/min or more, 110 μmol/min or more, 115 μmol/min or more, 120 μmol/min or more, 125 μmol/min or more, 130 μmol/min or more, 135 μmol/min or more, 140 μmol/min or more, 145 μmol/min or more, 150 μmol/min or more, 155 μmol/min or more, 160 μmol/min or more, 165 μmol/min or more, 170 μmol/min or more, 175 μmol/min or more, 180 μmol/min or more, 185 μmol/min or more, 190 μmol/min or more, 195 μmol/min or more, 200 μmol/min or more, 205 μmol/min or more, 210 μmol/min or more, 215 μmol/min or more, 220 μmol/min or more, 225 μmol/min or more, 230 μmol/min or more, 235 μmol/min or more, 240 μmol/min or more, 245 μmol/min or more, 250 μmol/min or more, 275 μmol/min or more, 300 μmol/min or more, 325 μmol/min or more, 350 μmol/min or more, 375 μmol/min or more, 400 μmol/min or more, 425 μmol/min or more, 450 μmol/min or more, 475 μmol/min or more, 500 μmol/min or more, 550 μmol/min or more, 600 μmol/min or more, 650 μmol/min or more, 700 μmol/min or more, 750 μmol/min or more, 800 μmol/min or more, 850 μmol/min or more, or 900 μmol/min or more). In some examples, the first precursor is provided at a flow rate of 1000 μmole/minute or less (e.g., 950 μmol/min or less, 900 μmol/min or less, 850 μmol/min or less, 800 μmol/min or less, 750 μmol/min or less, 700 μmol/min or less, 650 μmol/min or less, 600 μmol/min or less, 550 μmol/min or less, 500 μmol/min or less, 475 μmol/min or less, 450 μmol/min or less, 425 μmol/min or less, 400 μmol/min or less, 375 μmol/min or less, 350 μmol/min or less, 325 μmol/min or less, 300 μmol/min or less, 275 μmol/min or less, 250 μmol/min or less, 245 μmol/min or less, 240 μmol/min or less, 235 μmol/min or less, 230 μmol/min or less, 225 μmol/min or less, 220 μmol/min or less, 215 μmol/min or less, 210 μmol/min or less, 205 μmol/min or less, 200 μmol/min or less, 195 μmol/min or less, 190 μmol/min or less, 185 μmol/min or less, 180 μmol/min or less, 175 μmol/min or less, 170 μmol/min or less, 165 μmol/min or less, 160 μmol/min or less, 155 μmol/min or less, 150 μmol/min or less, 145 μmol/min or less, 140 μmol/min or less, 135 μmol/min or less, 130 μmol/min or less, 125 μmol/min or less, 120 μmol/min or less, 115 μmol/min or less, 110 μmol/min or less, 105 μmol/min or less, 100 μmol/min or less, 95 μmol/min or less, 90 μmol/min or less, 85 μmol/min or less, 80 μmol/min or less, 75 μmol/min or less, 70 μmol/min or less, 65 μmol/min or less, 60 μmol/min or less, 55 μmol/min or less, 50 μmol/min or less, 45 μmol/min or less, 40 μmol/min or less, 35 μmol/min or less, 30 μmol/min or less, 25 μmol/min or less, 20 μmol/min or less, 15 μmol/min or less, 10 μmol/min or less, 9 μmol/min or less, 8 μmol/min or less, 7 μmol/min or less, 6 μmol/min or less, 5 μmol/min or less, 4 μmol/min or less, 3 μmol/min or less, 2.5 μmol/min or less, 2 μmol/min or less, 1.5 μmol/min or less, 1 μmol/min or less, 0.5 μmol/min or less, 0.1 μmol/min or less, or 0.05 μmol/min or less). The flow rate of the first precursor can range from any of the minimum values described above to any of the maximum values described above. For example, the first precursor can be provided at a flow rate of from 0.01 to 1000 μmole/minute (e.g., from 0.01 to 500 μmole/minute, from 500 to 1000 μmole/minute, from 0.01 to 200 μmole/minute, from 200 to 400 μmole/minute, from 400 to 600 μmole/minute, from 600 to 800 μmole/minute, from 800 to 1000 μmole/minute, from 0.01 to 800 μmole/minute, from 0.01 to 600 μmole/minute, from 0.01 to 400 μmole/minute, from 0.01 to 100 μmole/minute, from 0.01 to 50 μmole/minute, from 0.1 to 1000 μmole/minute, from 1 to 1000 μmole/minute, from 50 to 1000 μmole/minute, from 100 to 1000 μmole/minute, from 200 to 1000 μmole/minute, from 400 to 1000 μmole/minute, from 600 to 1000 μmole/minute, from 0.1 to 900 μmole/minute, from 0.5 to 800 μmole/minute, or from 1 to 250 μmole/minute).

In some examples, the first precursor can be provided at a flow rate of from 1 to 250 μmole/minute (e.g., from 1 to 125 μmol/min, from 125 to 250 μmol/min, from 1 to 50 μmol/min, from 50 to 100 μmol/min, from 100 to 150 μmol/min, from 150 to 200 μmol/min, from 200 to 250 μmol/min, from 5 to 250 μmol/min, from 10 to 250 μmol/min, from 15 to 250 μmol/min, from 20 to 250 μmol/min, from 25 to 250 μmol/min, from 30 to 250 μmol/min, from 40 to 250 μmol/min, from 50 to 250 μmol/min, from 75 to 250 μmol/min, from 100 to 250 μmol/min, from 125 to 250 μmol/min, from 1 to 225 μmol/min, from 1 to 200 μmol/min, from 1 to 175 μmol/min, from 1 to 150 μmol/min, from 1 to 125 μmol/min, from 1 to 100 μmol/min, from 1 to 75 μmol/min, from 1 to 50 μmol/min, from 5 to 225 μmol/min, from 10 to 200 μmol/min, from 15 to 175 μmol/min, from 20 to 150 μmol/min, or from 25 to 125 μmol/min).

In some examples, the second precursor comprises O₂ or an oxygen-containing precursor, such as H₂O. In some examples, the second precursor comprises O₂.

In some examples, the first temperature is 600 °C or more (e.g., 625 °C or more, 650 °C or more, 675 °C or more, 700 °C or more, 725 °C or more, 750 °C or more, 775 °C or more, 800 °C or more, 825 °C or more, 850 °C or more, 875 °C or more, 900 °C or more, 925 °C or more, 950 °C or more, 975 °C or more, 1000 °C or more, 1025 °C or more, or 1050 °C or more). In some examples, the first temperature is 1100 °C or less (e.g., 1075 °C or less, 1050 °C or less, 1025 °C or less, 1000 °C or less, 975 °C or less, 950 °C or less, 925 °C or less, 900 °C or less, 875 °C or less, 850 °C or less, 825 °C or less, 800 °C or less, 775 °C or less, 750 °C or less, 725 °C or less, 700 °C or less, 675 °C or less, or 650 °C or less). The first temperature can range from any of the minimum values described above to any of the maximum values described above. For example, the first temperature can be from 600 °C to 1100 °C (e.g., from 600 850 °C, from 850 °C to 1100 °C, from 600 °C to 700 °C, from 700 °C to 800 °C, from 800 °C to 900 °C, from 900 °C to 1000 °C, from 1000 1100 °C, from 700 °C to 1100 °C, from 800 °C to 1100 °C, from 900 °C to 1100 °C, from 600 °C to 1000 °C, from 600 °C to 900 °C, from 600 °C to 800 °C, from 650 °C to 1050 °C, or from 650 °C to 1000 °C).

In some examples, the first temperature can be from 650 °C to 1000 °C (e.g., from 650 °C to 825 °C, from 825 °C to 1000 °C, from 650 °C to 700 °C, from 700 °C to 750 °C, from 750 °C to 800 °C, from 800 °C to 850 °C, from 850 °C to 900 °C, from 900 950 °C, from 950 °C to 1000 °C, from 650 °C to 900 °C, from 650 °C to 800 °C, from 700 °C to 1000 °C, from 800 °C to 1000 °C, from 675 °C to 975 °C, or from 700 °C to 950 °C).

In some examples, the method produces the first layer at a growth rate of 1 μm/hour or more (e.g., 1.5 μm/hour or more, 2 μm/hour or more, 2.5 μm/hour or more, 3 μm/hour or more, 3.5 μm/hour or more, 4 μm/hour or more, 4.5 μm/hour or more, 5 μm/hour or more, 5.5 μm/hour or more, 6 μm/hour or more, 6.5 μm/hour or more, 7 μm/hour or more, 7.5 μm/hour or more, 8 μm/hour or more, 8.5 μm/hour or more, 9 μm/hour or more, 9.5 μm/hour or more, 10 μm/hour or more, 11 μm/hour or more, 12 μm/hour or more, 13 μm/hour or more, 14 μm/hour or more, 15 μm/hour or more, 20 μm/hour or more, 25 μm/hour or more, 30 μm/hour or more, 35 μm/hour or more, 40 μm/hour or more, 45 μm/hour or more, 50 μm/hour or more, 55 μm/hour or more, 60 μm/hour or more, 65 μm/hour or more, 70 μm/hour or more, 75 μm/hour or more, 80 μm/hour or more, 85 μm/hour or more, or 90 μm/hour or more). In some examples, the method produces the first layer at a growth rate of 100 μm/hour or less (e.g., 95 μm/hour or less, 90 μm/hour or less, 85 μm/hour or less, 80 μm/hour or less, 75 μm/hour or less, 70 μm/hour or less, 65 μm/hour or less, 60 μm/hour or less, 55 μm/hour or less, 50 μm/hour or less, 45 μm/hour or less, 40 μm/hour or less, 35 μm/hour or less, 30 μm/hour or less, 25 μm/hour or less, 20 μm/hour or less, 15 μm/hour or less, 14 μm/hour or less, 13 μm/hour or less, 12 μm/hour or less, 11 μm/hour or less, 10 μm/hour or less, 9.5 μm/hour or less, 9 μm/hour or less, 8.5 μm/hour or less, 8 μm/hour or less, 7.5 μm/hour or less, 7 μm/hour or less, 6.5 μm/hour or less, 6 μm/hour or less, 5.5 μm/hour or less, 5 μm/hour or less, 4.5 μm/hour or less, 4 μm/hour or less, 3.5 μm/hour or less, 3 μm/hour or less, 2.5 μm/hour or less, or 2 μm/hour or less). The growth rate can range from any of the minimum values described above to any of the maximum values described above. For example, the method can produce the first layer at a growth rate of from 1 μm/hour to 100 μm/hour (e.g., from 1 to 50 μm/hour, from 50 to 100 μm/hour, from 1 to 20 μm/hour, from 20 to 40 μm/hour, from 40 to 60 μm/hour, from 60 to 80 μm/hour, from 80 to 100 μm/hour, from 2 to 100 μm/hour, from 3 to 100 μm/hour, from 5 to 100 μm/hour, from 10 to 100 μm/hour, from 15 to 100 μm/hour, from 20 to 100 μm/hour, from 30 to 100 μm/hour, from 40 to 100 μm/hour, from 60 to 100 μm/hour, from 1 to 80 μm/hour, from 1 to 60 μm/hour, or from 3 to 60 μm/hour).

In some examples, the method can produce the first layer at a growth rate of from 3 μm/hour to 60 μm/hour (e.g., from 3 to 30 μm/hour, from 30 μm/hour to 60 μm/hour, from 3 to 20 μm/hour, from 20 μm/hour to 40 μm/hour, from 40 to 60 μm/hour, from 3.5 to 60 μm/hour, from 4 to 60 μm/hour, from 4.5 to 60 μm/hour, from 5 to 60 μm/hour, from 5.5 to 60 μm/hour, from 6 to 60 μm/hour, from 7 to 60 μm/hour, from 8 to 60 μm/hour, from 9 to 60 μm/hour, from 10 to 60 μm/hour, from 15 to 60 μm/hour, from 20 to 60 μm/hour, from 25 to 60 μm/hour, from 5 to 55 μm/hour, or from 10 to 50 μm/hour).

In some examples, the first pressure is 5 torr or more (e.g., 10 torr or more, 15 torr or more, 20 torr or more, 25 torr or more, 30 torr or more, 35 torr or more, 40 torr or more, 45 torr or more, 50 torr or more, 60 torr or more, 70 torr or more, 80 torr or more, 90 torr or more, 100 torr or more, 125 torr or more, 150 torr or more, 175 torr or more, 200 torr or more, 250 torr or more, 300 torr or more, 350 torr or more, 400 torr or more, 450 torr or more, 500 torr or more, or 550 torr or more). In some examples, the first pressure is 600 torr or less (e.g., 550 torr or less, 500 torr or less, 450 torr or less, 400 torr or less, 350 torr or less, 300 torr or less, 250 torr or less, 200 torr or less, 175 torr or less, 150 torr or less, 125 torr or less, 100 torr or less, 90 torr or less, 80 torr or less, 70 torr or less, 60 torr or less, 50 torr or less, 45 torr or less, 40 torr or less, 35 torr or less, 30 torr or less, 25 torr or less, 20 torr or less, 15 torr or less, or 10 torr or less). The first pressure can range from any of the minimum values described above to any of the maximum values described above. For example, the first pressure can be from 5 to 600 torr (e.g., from 5 to 300 torr, from 300 to 600 torr, from 5 to 200 torr, from 200 torr to 400 torr, from 400 to 600 torr, from 5 to 500 torr, from 5 to 400 torr, from 5 to 100 torr, from 10 to 600 torr, from 25 to 600 torr, from 50 to 600 torr, from 100 to 600 torr, from 200 to 600 torr, from 10 torr to 550 torr, from 25 torr to 500 torr, or from 50 torr to 450 torr).

In some examples, the method further comprises introducing a third precursor comprising a dopant, such that the composition further comprises the dopant. In some examples, the third precursor is provided as a fluid, such as a gas. In some examples, the third precursor comprises a Si containing precursor, a Ge containing precursor, a Sn containing precursor, a Mg containing precursor, or a combination thereof. In some examples, the third precursor comprises silane (SiH₄), germane (GeH₄), disilane (Si₂H₆), bis(cyclopentadienyl)magnesium (Cp₂Mg), bis(methylcyclopentadienyl)magnesium ((MeCp)₂Mg), or a combination thereof. In some examples, the third precursor comprises silane (SiH₄).

In some examples, the first precursor, the second precursor, the third precursor (when present), or a combination thereof are independently provided with a carrier gas. In some examples, the carrier gas comprises argon, helium, H₂, N₂, and the like, or combinations thereof.

In some examples, the method further comprises depositing the second layer on the first layer.

Also disclosed herein are compositions made by any of the methods disclosed herein.

Also disclosed herein are devices comprising any of the compositions disclosed herein. For example, the device can comprise a vertical power device. In some examples, the device comprises a vertical Schottky barrier diode such as a vertical trench Schottky barrier diode, a PN heterojunction power diode, or a combination thereof. In some examples, the device comprises an optical device, an electronic device, an optoelectronic device, or a combination thereof.

Also disclosed herein are methods of use of any of the compositions disclosed herein.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the devices and methods described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in °C or is at ambient temperature, and pressure is at or near atmospheric. There are numerous variations and combinations of measurement conditions, e.g., component concentrations, temperatures, pressures and other measurement ranges and conditions that can be used to optimize the described process.

### Example 1—Development of Thick (010) β—Ga2O3 Films on Miscut Substrates for Vertical Power Devices

β—Ga₂O₃ has been considered as a promising semiconductor material for the development of next-generation high power electronic devices because of its advantageous properties, which include its ultrawide bandgap energy (4.8 eV), controllable n-type doping, and high anticipated breakdown field strength (8 MV/cm) [1]. Another advantage of β—Ga₂O₃ over other wide (GaN, SiC) and ultrawide (diamond, AIN) bandgap materials is its availability of single crystal high-quality native substrates with various orientations grown via scalable melt growth techniques [2]. These promising advantages have fostered the continuous development of high performance β—Ga₂O₃ based lateral and vertical devices with increasingly better performance [3-5]. In comparison to their lateral counterparts, vertical β—Ga₂O₃ devices in the form of Schottky barrier [4-7], p-n heterojunction [8], or metal-insulator-semiconductor (MIS) diodes [9] have been demonstrated with promising current capability, field management and scaling feasibility.

Despite the technology still being in its early development stage, β—Ga₂O₃ vertical trench Schottky barrier diodes have already been demonstrated with low reverse leakage current and high breakdown voltage exceeding 2.8 kV [5]. However, performance of the β—Ga₂O₃ power devices is still well below its projected limit. While several approaches have been implemented to improve the breakdown voltage, such as implanted edge termination, field plates, p-NiOₓ rings, fin structures, and high-k oxide field plates [7-11], the performance of β—Ga₂O₃ power devices fabricated on homoepitaxial β—Ga₂O₃ layers still lag behind the conventional GaN and SiC based SBDs in terms of breakdown voltage and leakage current. Despite its availability of high-quality native substrates with lower dislocation density [2], the difficulty in epitaxial growth of high-quality thick drift layers with smooth surface morphology and controllable doping are factors that can limit the performance of β—Ga₂O₃ power devices.

For the development of high-power electronic devices with high reverse breakdown voltage, a thick drift layer with smooth surface morphology, lower controllable doping and impurities is beneficial, indicating the need for higher growth rates while preserving the epilayer quality. Although epitaxial development of β—Ga₂O₃ layers on (010) oriented β—Ga₂O₃ substrates have been demonstrated with relatively fast growth rates by different growth methods, such as low-pressure chemical vapor deposition (LPCVD) [12] and metal-organic chemical vapor deposition (MOCVD) [13], the growth of thicker films often leads to the formation of three-dimensional (3D) islands on the growth surface, resulting in degraded performance in power devices including non-ideal forward transport, high leakage current, and high on-resistance. Prior studies on MOCVD homoepitaxial growth of (100) β—Ga₂O₃ on on-axis β—Ga₂O₃ substrates lead to the formation of stacking faults and twin lamellae in epitaxial film [14]. Although by introducing appropriate miscut angles on the substrates, step-flow growth of β—Ga₂O₃ thin films on (100) plane could be achieved, the growth rates on (100) plane was found to be significantly lower than the (010) plane [15], implying the challenges to develop thick β—Ga₂O₃ drift layer on (100) oriented β—Ga₂O₃ substrates. While the growth of thick β—Ga₂O₃ with relatively fast growth rate (>5 μm/hr) have been demonstrated on (001) Ga₂O₃ substrates by halide vapor phase epitaxy (HVPE) [16], this method produces films with rougher surface morphology that require additional chemo-mechanical polishing (CMP) process prior device fabrication. This process not only increases the processing cost but also could introduce impurities/contaminants onto the polished surface. Recently, utilizing trimethylgallium (TMGa) as the Ga precursor, MOCVD growth of high quality β—Ga₂O₃ thin films on (010) oriented on-axis β—Ga₂O₃ substrates (without miscuts) was demonstrated at growth rate of <=3 μm/hr [13]. The surface morphology of β—Ga₂O₃ films grown on on-axis (010) oriented β—Ga₂O₃ substrates, however, becomes rougher with the formation of 3D islands, as the growth rate and/or film thickness increases. Therefore, a technique using a scalable growth method that can generate high quality β—Ga₂O₃ with controllable doping, faster growth rate, and smooth surface morphology is needed.

Herein, rather than using the on-axis (010) oriented β—Ga₂O₃ substrates, a method is proposed to develop high quality thick β—Ga₂O₃ films with much faster growth rates and smooth surface morphology via MOCVD growth method and using (010) β—Ga₂O₃ substrates with miscut angles. In this method, the surface steps of off-axis (010) β—Ga₂O₃ substrates act as the preferred incorporation sites for the Ga adatoms and thus promote more uniform nucleation with better surface morphology. For the growth of β—Ga₂O₃ films, TMGa is used as Ga precursor. Argon (Ar) or nitrogen (N₂) can be used as the carrier gas. The typical growth temperature can be varied between 650-1000 °C, and the typical chamber pressure can be varied between 5 and 600 torr. Si donor can be used as an effective n-type doping in the MOCVD grown β—Ga₂O₃ films. The use of off-axis (010) Ga₂O₃ substrates is only required when TMGa molar flow rate is relatively high to promote a growth rate >=3 μm/hr.

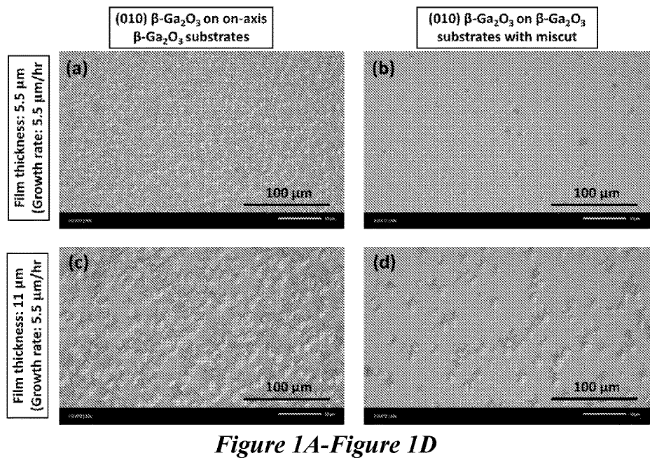

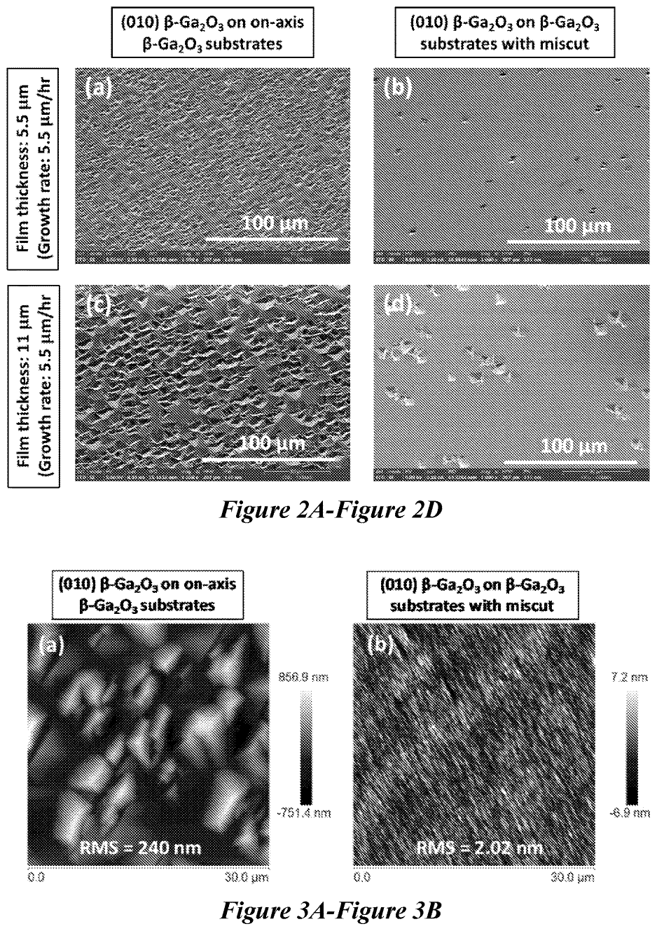

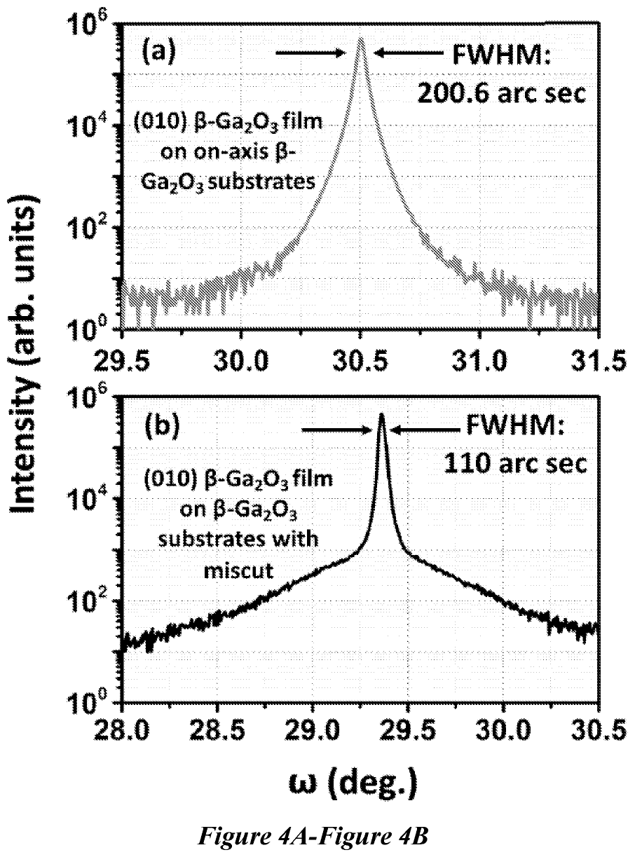

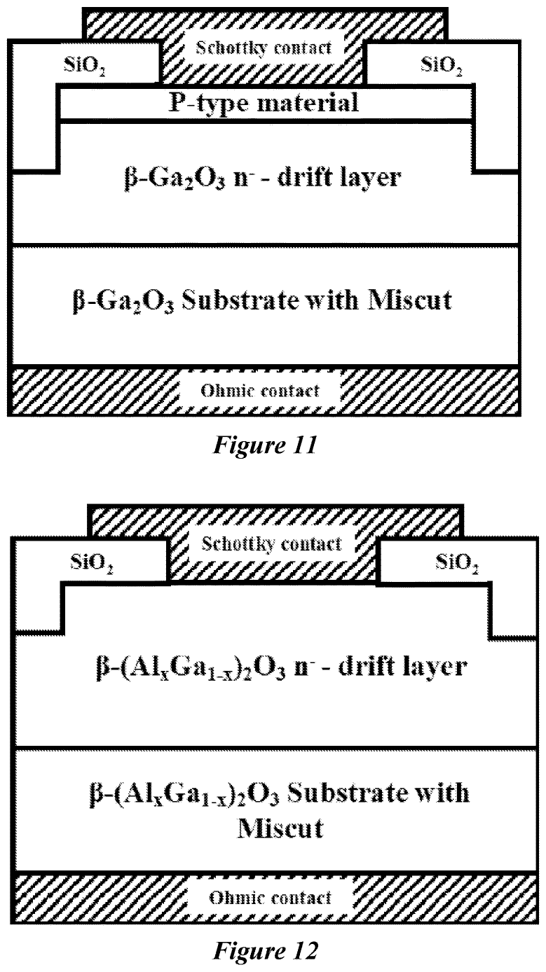

As an example, a proof-of-concept set of experiments were demonstrated, as described below. To investigate the influence of substrate miscut on surface morphology, the growth of β—Ga₂O₃ films was performed on (010) oriented β—Ga₂O₃ substrates without (on-axis) and with (off-axis) miscuts. A miscut angle of 1.12° was used for the growth of β—Ga₂O₃ films on off-axis substrates. FIG. 1A-FIG. 1D compares the optical macroscopic surface morphology of β—Ga₂O₃ films grown on on-axis (FIG. 1A, FIG. 1C) and off-axis (FIG. 1B, FIG. 1D) (010) β—Ga₂O₃ substrates with different film thicknesses of 5.5 μm (FIG. 1A, FIGS. 1B) and 11 μm (FIG. 1C, FIG. 1D). All the films were grown with 5.5 μm/hr growth rate. Both on-and off-axes substrates were co-loaded in the growth chamber to have better comparison. The corresponding scanning electron microscopy (SEM) images of β—Ga₂O₃ films grown on on-axis (FIG. 2A, FIG. 2C) and off-axis (FIG. 2B, FIG. 2D) (010) oriented β—Ga₂O₃ substrates are also shown in FIG. 2A-FIG. 2D. The surface of β—Ga₂O₃ films grown on β—Ga₂O₃ substrates without any intentional miscuts exhibits dense 3D bump like structures as shown in FIG. 1A, FIG. 1C, FIG. 2A, and FIG. 2C. In contrast, by introducing a small miscut angle of 1.12° on the substrates, the surface of β—Ga₂O₃ films becomes much smoother with significantly less dense bumps on the growth surface (FIG. 1B, FIG. 1D, FIG. 2B, FIG. 2D). The surface atomic force microscopy (AFM) images of 5.5 μm thick β—Ga₂O₃ films grown on β—Ga₂O₃ substrates without and with miscut angle are also compared as shown in FIG. 3A-FIG. 3B. The RMS roughness of β—Ga₂O₃ films grown on β—Ga₂O₃ substrates significantly reduces from 240 nm to 2.02 nm due to the growth on off-axis substrate, indicating that the miscut substrate enhances the epitaxial growth of thick β—Ga₂O₃ films with uniform surface morphologies. The x-ray diffraction (XRD) rocking curve full width at half maximum (FWHM) from (020) reflection of-Ga₂O₃ films (5.5 μm thick) also reduces from 200.6 to 110 arcsec due to the introduction of miscut substrate, as shown in FIG. 4A-FIG. 4B, indicating better crystalline quality of the film grown on β—Ga₂O₃ substrates with miscut angle.

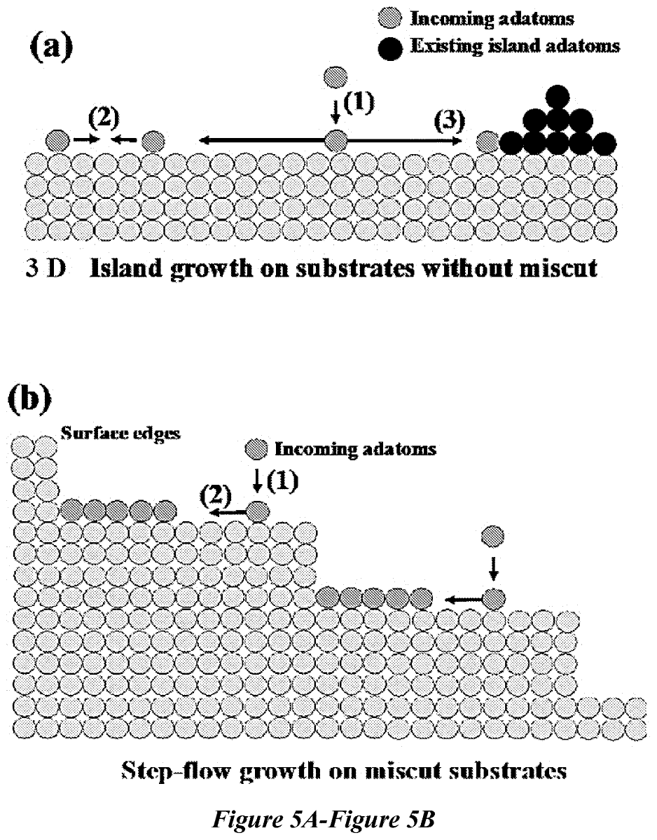

The introduction of miscut angle on β—Ga₂O₃ substrates with appropriate angles and orientation enhances the uniformity of the growth surface, as the surface steps/edges provide incorporation sites for the incoming Ga adatoms on the growth surface. A schematic on 3D Island formation on on-axis substrates is shown in FIG. 5A. In the absence of energetically favorable nucleation sites on β—Ga₂O₃ substrate without miscuts, the incoming adatoms attach to (010) surface and the growth proceeds laterally by the attachment of further adatoms, forming 3D islands on the growth surface and finally generating bump like 3D structures by the coalescence of 3D islands as can be seen from the surface SEM images in FIG. 2A and FIG. 2C. This issue happens when the TMGa molar flow rate is relatively high and diffusion of Ga adatoms on the growth surface becomes shorter, which promotes the island growth mode. In case of substrates with miscuts as shown in FIG. 5B, the adatoms diffusion across the surface and energetically preferred incorporation at step edges compete with 3D island nucleation. The probability of 3D islands forming on the terraces between the steps decreases due to competition with step edges. The width of the terraces and the diffusion length of adatoms on the surface ultimately determine whether 3D island growth or step-flow growth dominates. The density of islands largely depends on the miscut-angle and orientations for a given growth conditions (e.g., temperature, pressure, flux of adatoms). The surface edges on miscut substrates provide more nucleation sites, suppressing the local 3D island growth modes and enhancing the uniformity of surface morphology without forming bumps on growth surface.

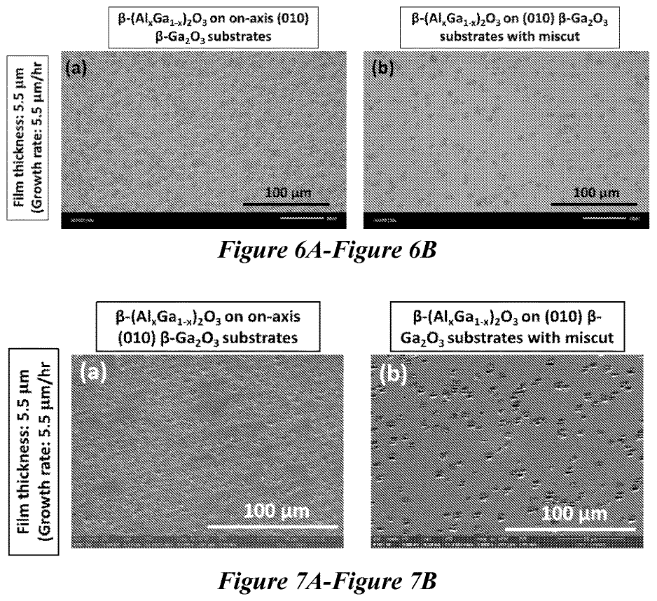

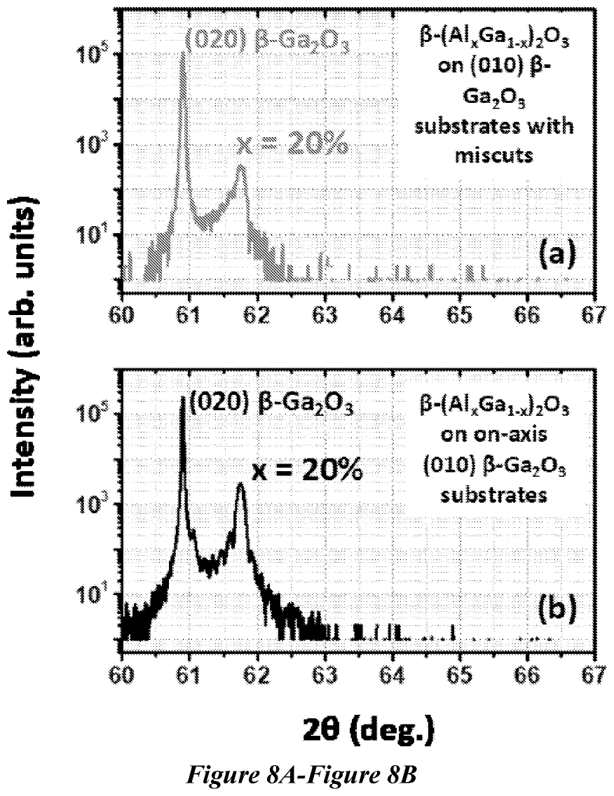

In addition, the surface morphologies of 5.5 μm thick β—(AlₓGa₁₋ₓ)₂O₃ films grown with low Al composition of 2% are also compared for the growth on both off-axis and on-axis β—Ga₂O₃ substrates. The density of 3D structures on the growth surface significantly reduces for the films grown on substrates with miscuts as compared to the non-miscut substrates, as shown in the optical and SEM images in FIG. 6A-FIG. 6B and FIG. 7A-FIG. 7B, respectively. The Al incorporation in β—(AlₓGa₁₋ₓ)₂O₃ films grown on both miscut and non-miscut substrates are also compared with XRD ω-2θ scan spectra in FIG. 8A-FIG. 8B. Both β—(AlₓGa₁₋ₓ)₂O₃ films were co-loaded in the growth chamber and were targeted for 60 nm thickness. The (020) β—Ga₂O₃ peak in FIG. 8A-FIG. 8B corresponds to the signal from the (010) β—Ga₂O₃ substrates. Both β—(AlₓGa₁₋ₓ)₂O₃ films grown on miscut and non-miscut substrates show a similar Al incorporation of 20% with strong intensity diffraction peak, implying high quality epitaxial layers grown on β—Ga₂O₃ substrates, regardless of the miscut of the substrates. This indicates it is feasible to achieve a similar range of Al composition on miscut substrates. While thick β—(AlₓGa₁₋ₓ)₂O₃ films with low Al composition of <3% and better surface morphologies can be achieved on off-axis β—Ga₂O₃ substrates as shown in FIG. 6B and FIG. 7B, the growth of thick β—(AlₓGa₁₋ₓ)₂O₃ film on β—Ga₂O₃ substrates with higher Al composition is challenging due to the higher lattice mismatch between the substrate and epilayer. The development of lattice matched β—(AlₓGa₁₋ₓ)₂O₃ substrates with proper miscut angles and orientations will potentially pave the way to achieve thick β—(AlₓGa₁₋ₓ)₂O₃ films with higher Al composition and thus higher critical breakdown field strength.

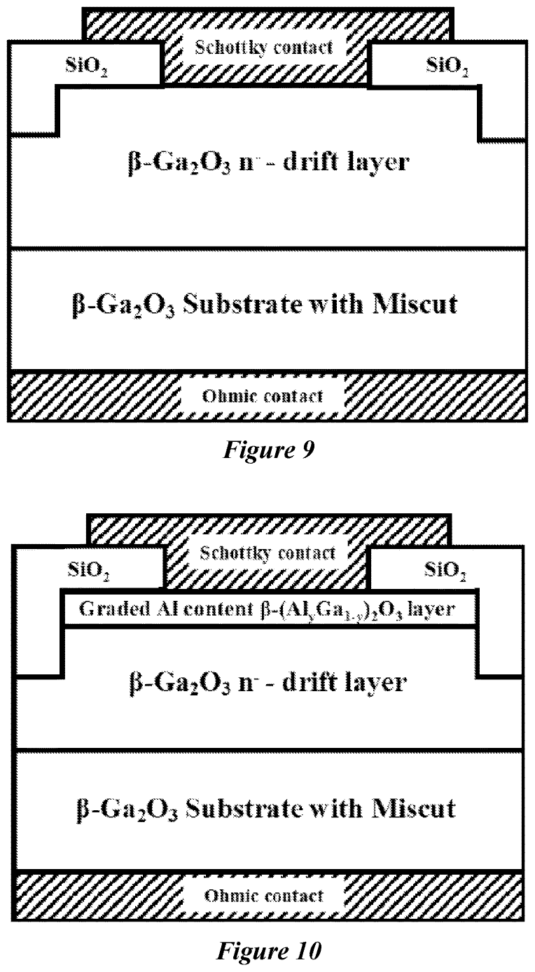

Aligned with this idea, vertical Schottky barrier diodes with/without using graded Al content β—(AlₓGa₁₋ₓ)₂O₃ layers can be developed based on thick β—Ga₂O₃ films grown on (010) β—Ga₂O₃ substrates with appropriate miscut angles as shown in the schematics in FIG. 9 and FIG. 10, respectively. Moreover, β—Ga₂O₃ based PN heterojunction power diodes, as depicted in FIG. 11 can be fabricated in accordance with the present invention. Such thick β—Ga₂O₃ drift layer with smooth surface morphology can decrease reverse leakage current and enhance the device breakdown limits for high power operations.

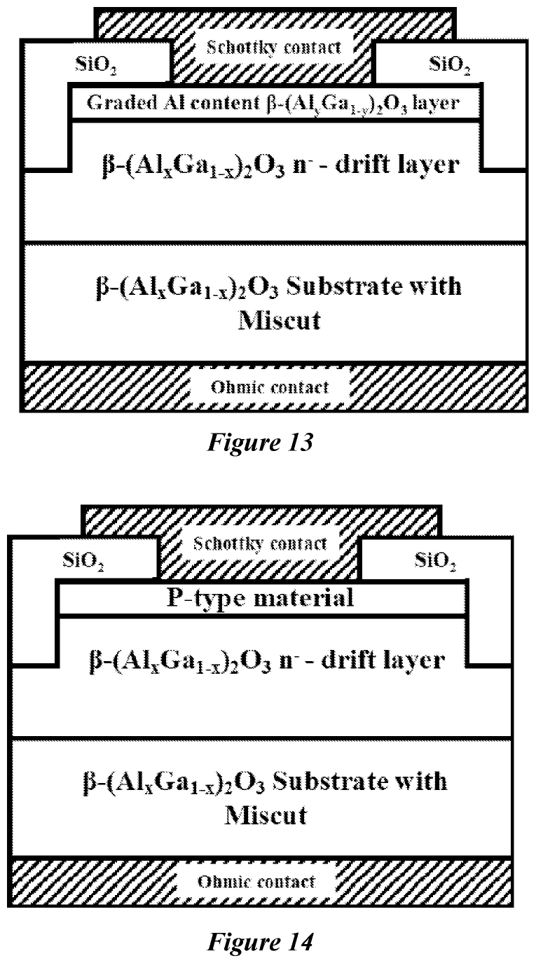

All the above proposed structures can also be developed using high quality β—(AlₓGa₁₋ₓ)₂O₃ layers grown on lattice-matched off-axis (AlₓGa₁₋ₓ)₂O₃ substrates with the similar Al composition of the drift layer as illustrated in the schematic of FIG. 12-FIG. 14. As compared to the power devices based on β—Ga₂O₃, the growth of lattice-matched epi-layer on β—(AlₓGa₁₋ₓ)₂O₃ substrates with proper miscut angles and orientations can provide the opportunity to achieve even higher breakdown voltage in high power devices due to the increase of the bandgap energy with increasing Al compositions.

In summary, the MOCVD epitaxial development of high quality and thick β—Ga₂O₃ and β—(AlₓGa₁₋ₓ)₂O₃ drift layers on off-axis substrates with fast growth rates and enhanced surface morphology can provide a new route to develop next generation vertical power devices. The drift layer growth rate potentially can exceed 10 μm/hr with total drift layer thickness of 100 μm or more, indicating the potential of achieving the breakdown voltage of these devices above 20 kV.

### References

1. Green A J et al. β-Gallium oxide power electronics. APL Mater. 2022, 10, 029201.
2. Kuramata A et al. High-quality β—Ga₂O₃ single crystals grown by edge-defined film-fed growth. Jpn. J. Appl. Phys., 2016, Part 1 55, 1202A2.
3. Li W et al. Single and multi-fin normally-off Ga₂O₃ vertical transistors with a breakdown voltage over 2.6 kV. 2019 IEEE International Electron Devices Meeting (IEDM) 2019, pp. 12.4.1-12.4.4.
4. Hu Z et al. Field-Plated Lateral β—Ga₂O₃ Schottky Barrier Diode With High Reverse Blocking Voltage of More Than 3 kV and High DC Power Figure-of-Merit of 500 MW/cm². IEEE Electron Device Lett. 2018, 39, 1564-1567.
5. Li W et al. Field-Plated Ga₂O₃ Trench Schottky Barrier Diodes With a BV²/Ron, sp of up to 0.95 GW/cm². IEEE Electron Device Lett. 2020, 41, 107-110.
6. Konishi K et al. 1-kV vertical Ga₂O₃ field-plated Schottky barrier diodes. Appl. Phys. Lett. 2017, 110, 103506.
7. Sasaki K et al. First Demonstration of Ga₂O₃ Trench MOS-Type Schottky Barrier Diodes. IEEE Electron Device Lett. 2017, 38, 783-785.
8. Yan Q et al. β—Ga₂O₃ hetero-junction barrier Schottky diode with reverse leakage current modulation and BV²/Ron, sp value of 0.93 GW/cm². Appl. Phys. Lett. 2021, 118, 122102.
9. Li W et al. 1.5 kV Vertical Ga₂O₃ Trench-MIS Schottky Barrier Diodes, 2018 76th Device Research Conference (DRC), 2018, pp. 1-2, doi: 10.1109/DRC.2018.8442245.
10. Lin CH et al. Vertical Ga₂O₃ Schottky Barrier Diodes With Guard Ring Formed by Nitrogen-Ion Implantation. IEEE Electron Device Lett. 2019, 40, 1487-1490.
11. Zhou H et al. High-Performance Vertical β—Ga₂O₃ Schottky Barrier Diode With Implanted Edge Termination. IEEE Electron Device Lett. 2019, 40, 1788-1791.
12. Zhang Y et al. High-temperature low-pressure chemical vapor deposition of-Ga₂O₃. J. Vac. Sci. Technol. A 2020, 38, 050806.
13. Meng L et al. High-Mobility MOCVD β—Ga₂O₃ Epitaxy with Fast Growth Rate Using Trimethylgallium. Cryst. Growth Des. 2022, 22, 3896-39.
14. Schewski R et al. Evolution of planar defects during homoepitaxial growth of β—Ga₂O₃ layers on (100) substrates-A quantitative model, J. Appl. Phys. 2016, 120, 225308.
15. Sasaki K et al. Device-Quality β—Ga₂O₃ Epitaxial Films Fabricated by Ozone Molecular Beam Epitaxy, Appl. Phys. Express 2012, 5 (3), 035502 (2012).
16. Murakami H et al. Homoepitaxial growth of β—Ga₂O₃ layers by halide vapor phase epitaxy. Appl. Phys. Express 2015, 8, 015503.

### EXEMPLARY ASPECTS

In view of the described compositions, devices, systems, and methods, herein below are described certain more particularly described aspects of the inventions. The particularly recited aspects should not, however, be interpreted to have any limiting effect on any different claims containing different or more general teachings described herein or that the “particular” aspects are somehow limited in some way other than the inherent meanings of the language and formulas literally used therein.
Example 1: A composition comprising a first layer disposed on a substrate, wherein the first layer comprises β—(AlₓGa₁₋ₓ)₂O₃ where x is from 0 to 1, and the substrate comprises β—(Al_{z}Ga_{1-z})₂O₃ having a miscut angle of 5° or less, where z is from 0 to 1.
Example 2: The composition of any examples herein, particularly example 1, wherein the miscut angle is 2° or less, 1.5° or less, or 1.25° or less.
Example 3: The composition of any examples herein, particularly example 1 or example 2, wherein the first layer has an average thickness of from 0.1 μm to 1000 μm, or from 1 μm to 1000 μm.
Example 4: The composition of any examples herein, particularly examples 1-3, wherein the first layer has an average thickness of 1 μm or more, 5 μm or more, 10 μm or more, 50 μm or more, or 100 μm or more.
Example 5: The composition of any examples herein, particularly examples 1-4, wherein the first layer has a surface with an RMS roughness of 50 nm or less, 25 nm or less, 10 nm or less, 5 nm or less, 2.5 nm or less, or 1 nm or less as measured by AFM.
Example 6: The composition of any examples herein, particularly examples 1-5, wherein the first layer has a reflection rocking curve with a full width at half maximum (FWHM) of 500 arcsec or less, 200 arcsec or less, 150 arcsec or less, 125 arcsec or less, or 100 arcsec or less as measured x-ray diffraction (XRD).
Example 7: The composition of any examples herein, particularly examples 1-6, wherein the first layer has an (020) reflection rocking curve with a full width at half maximum (FWHM) of 500 arcsec or less, 200 arcsec or less, 150 arcsec or less, 125 arcsec or less, or 100 arcsec or less as measured x-ray diffraction (XRD).
Example 8: The composition of any examples herein, particularly examples 1-7, wherein the first layer further comprises a dopant.
Example 9: The composition of any examples herein, particularly example 8, wherein the dopant comprises an N-type dopant, such as Si.
Example 10: The composition of any examples herein, particularly examples 1-9, wherein x is 0.
Example 11: The composition of any examples herein, particularly examples 1-10, wherein z is 0.
Example 12: The composition of any examples herein, particularly examples 1-11, wherein z is 0 and x is 0.3 or less, 0.1 or less, or 0.03 or less.
Example 13: The composition of any examples herein, particularly examples 1-12, wherein the first layer and the substrate are substantially the same composition.
Example 14: The composition of any examples herein, particularly examples 1-13, wherein the substrate comprising β—(Al_{z}Ga_{1-z})₂O₃ has a crystal orientation of (010), (100), (001), or (−201).
Example 15: The composition of any examples herein, particularly examples 1-14, wherein the substrate comprising β—(Al_{z}Ga_{1-z})₂O₃ has a crystal orientation of (010).
Example 16: The composition of any examples herein, particularly examples 1-15, wherein x and z are both 0, such that the composition comprises a β—Ga₂O₃ layer disposed on a β—Ga₂O₃ miscut substrate.
Example 17: The composition of any examples herein, particularly examples 1-15, wherein the substrate comprises β—(AlₓGa₁₋ₓ)₂O₃, such that the composition comprises a β—(AlₓGa₁₋ₓ)₂O₃ layer disposed on a β—(AlₓGa₁₋ₓ)₂O₃ miscut substrate.
Example 18: The composition of any examples herein, particularly examples 1-17, wherein x and z are both 0, such that the composition comprises a β—Ga₂O₃ layer disposed on a (010) β—Ga₂O₃ miscut substrate.
Example 19: The composition of any examples herein, particularly examples 1-17, wherein the substrate comprises β—(AlₓGa₁₋ₓ)₂O₃, such that the composition comprises a β—(AlₓGa₁₋ₓ)₂O₃ layer disposed on a (010) β—(AlₓGa₁₋ₓ)₂O₃ miscut substrate.
Example 20: The composition of any examples herein, particularly examples 1-19, further comprising a second layer disposed on the first layer opposite the substrate, wherein the second layer comprises β—(Al_{y}Ga_{1-y})₂O₃ where y is from 0 to 1, a doped material (e.g., a p-type material), or a combination thereof.
Example 21: The composition of any examples herein, particularly example 20, wherein the composition of the second layer varies, such that the second layer has a compositional gradient, such as with thickness.
Example 22: The composition of any examples herein, particularly example 20 or example 21, wherein the second layer comprises-(Al_{y}Ga_{1-y})₂O₃ and the value of y varies across the layer, such as with thickness.
Example 23: A method of making the composition of any examples herein, particularly examples 1-22, the method comprising contacting a first precursor and a second precursor at a first temperature and a first pressure in the presence of the substrate, wherein the first precursor comprises gallium and/or aluminum and the second precursor comprises oxygen, to thereby react the first precursor and the second precursor to deposit the first layer on the substrate.
Example 24: The method of any examples herein, particularly example 23, wherein the method comprises metal organic chemical vapor deposition (MOCVD), molecular-beam epitaxy (MBE), hydride vapor phase epitaxy (HVPE), pulsed laser deposition (PLD), low pressure chemical vapor deposition (LPCVD), mist-CVD, or a combination thereof.
Example 25: The method of any examples herein, particularly example 23 or any examples herein, particularly example 24, wherein the method comprises metal organic chemical vapor deposition (MOCVD).
Example 26: The method of any examples herein, particularly examples 23-25, wherein the first precursor and/or the second precursor independently comprise(s) a fluid, such as a gas. Example 27: The method of any examples herein, particularly examples 23-26, wherein the first precursor comprises gallium.
Example 28: The method of any examples herein, particularly examples 23-27, wherein the first precursor comprises trimethylgallium (TMGa), triethylgallium (TEGa), pure Ga or Ga-containing precursors, or a combination thereof.
Example 29: The method of any examples herein, particularly examples 23-28, wherein the first precursor comprises trimethylgallium (TMGa), triethylgallium (TEGa), or a combination thereof.
Example 30: The method of any examples herein, particularly examples 23-29, wherein the first precursor comprises trimethylgallium (TMGa).
Example 31: The method of any examples herein, particularly examples 23-30, wherein the first precursor comprises aluminum.
Example 32: The method of any examples herein, particularly examples 23-31, wherein the first precursor comprises trimethylaluminum (TMAl), triethylaluminum (TEAl), or a combination thereof.
Example 33: The method of any examples herein, particularly examples 23-32, wherein the first precursor comprises trimethylgallium (TMGa), triethylgallium (TEGa), trimethylaluminum (TMAl), triethylaluminum (TEAl), or a combination thereof.
Example 34: The method of any examples herein, particularly examples 23-33, wherein the first precursor comprises gallium and aluminum.
Example 35: The method of any examples herein, particularly examples 23-34, wherein the first precursor comprises a gallium containing precursor and an aluminum containing precursor.
Example 36: The method of any examples herein, particularly examples 23-35, wherein the first precursor comprises a gallium containing precursor and an aluminum containing precursor, the gallium containing precursor comprising trimethylgallium (TMGa), triethylgallium (TEGa), or a combination thereof, and the aluminum containing precursor comprising trimethylaluminum (TMAl), triethylaluminum (TEAl).
Example 37: The method of any examples herein, particularly examples 23-36, wherein the first precursor is provided at a flow rate of from 0.01 to 1000 μmole/minute, such as from 1 to 250 μmole/minute.
Example 38: The method of any examples herein, particularly examples 23-37, wherein the second precursor comprises O₂ or an oxygen-containing precursor, such as H₂O.
Example 39: The method of any examples herein, particularly examples 23-38, wherein the second precursor comprises O₂.
Example 40: The method of any examples herein, particularly examples 23-39, wherein in the first temperature is from 600 °C to 1100 °C, such as from 650 °C to 1000 °C
Example 41: The method of any examples herein, particularly examples 23-40, wherein the method produces the first layer at a growth rate of 1 μm/hour or more, 3 μm/hour or more, 5.5 μm/hour or more, or 10 μm/hour or more.
Example 42: The method of any examples herein, particularly examples 23-41, wherein the first pressure is from 5 to 600 torr.
Example 43: The method of any examples herein, particularly examples 23-42, wherein the method further comprises introducing a third precursor comprising a dopant, such that the composition further comprises the dopant.
Example 44: The method of any examples herein, particularly example 43, wherein the third precursor is provided as a fluid, such as a gas.
Example 45: The method of any examples herein, particularly example 43 or example 44, wherein the third precursor comprises a Si containing precursor, a Ge containing precursor, a Sn containing precursor, a Mg containing precursor, or a combination thereof.
Example 46: The method of any examples herein, particularly examples 43-45, wherein the third precursor comprises silane (SiH₄), germane (GeH₄), disilane (Si₂H₆), bis(cyclopentadienyl)magnesium (Cp₂Mg), bis(methylcyclopentadienyl)magnesium ((MeCp)₂Mg), or a combination thereof.
Example 47: The method of any examples herein, particularly examples 43-46, wherein the third precursor comprises silane (SiH₄).
Example 48: The method of any examples herein, particularly examples 23-47, wherein the first precursor, the second precursor, the third precursor (when present), or a combination thereof are independently provided with a carrier gas.
Example 49: The method of any examples herein, particularly example 48, wherein the carrier gas comprises argon, helium, H₂, N₂, and the like, or combinations thereof.
Example 50: The method of any examples herein, particularly examples 23-49, further comprising depositing the second layer on the first layer.
Example 51: A composition made by the method of any examples herein, particularly examples 23-50.
Example 52: A device comprising the composition of any examples herein, particularly examples 1-22 or 51.
Example 53: The device of any examples herein, particularly example 52, wherein the device comprises a vertical power device.
Example 54: The device of any examples herein, particularly example 52 or example 53, wherein the device comprises a vertical Schottky barrier diode such as a vertical trench Schottky barrier diode, a PN heterojunction power diode, or a combination thereof.
Example 55: The device of any examples herein, particularly examples 52-54, wherein the device comprises an optical device, an electronic device, an optoelectronic device, or a combination thereof.
Example 56: A method of use of the composition of any examples herein, particularly examples 1-22 or 51.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The compositions, devices, and methods of the appended claims are not limited in scope by the specific methods described herein, which are intended as illustrations of a few aspects of the claims and any methods that are functionally equivalent are intended to fall within the scope of the claims. Various modifications of the compositions, devices, and methods in addition to those shown and described herein are intended to fall within the scope of the appended claims. Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

1. A composition comprising a first layer disposed on a substrate, wherein the first layer comprises β—(AlₓGa₁₋ₓ)₂O₃ where x is from 0 to 1, and the substrate comprises β—(Al_{z}Ga_{1-z})₂O₃ having a miscut angle of from greater than 0° to 5°, where z is from 0 to 1, wherein the first layer and the substrate are substantially the same composition, and wherein the substrate comprising β—(Al_{z}Ga_{1-z})₂O₃ has a crystal orientation of (010), (001), or (−201).

2. The composition of claim 1, wherein the miscut angle is 2° or less.

3. The composition of claim 1, wherein the first layer has an average thickness of from 0.1 μm to 1000 μm.

4. The composition of claim 1, wherein the first layer has an average thickness of from 1 μm to 1000 μm.

5. The composition of claim 1, wherein the first layer has a surface with an RMS roughness of 50 nm or less, as measured by AFM.

6. The composition of claim 1, wherein the first layer has a reflection rocking curve with a full width at half maximum (FWHM) of 500 arcsec or less, as measured x-ray diffraction (XRD).

7. The composition of claim 1, wherein the first layer has an (020) reflection rocking curve with a full width at half maximum (FWHM) of 500 arcsec or less, measured x-ray diffraction (XRD).

8. The composition of claim 1, wherein the first layer further comprises a dopant.

9. (canceled)

10. The composition of claim 1, wherein x is 0.

11. The composition of claim 1, wherein z is 0.

12. (canceled)

13. (canceled)

14. (canceled)

15. The composition of claim 1, wherein the substrate comprising β—(Al_{z}Ga_{1-z})₂O₃ has a crystal orientation of (010).

16. The composition of claim 1, wherein x and z are both 0, such that the composition comprises a β—Ga₂O₃ layer disposed on a β—Ga₂O₃ miscut substrate.

17. The composition of claim 1, wherein the substrate comprises β—(AlₓGa₁₋ₓ)₂O₃, such that the composition comprises a β—(AlₓGa₁₋ₓ)₂O₃ layer disposed on a β—(AlₓGa₁₋ₓ)₂O₃ miscut substrate.

18. The composition of claim 1 wherein x and z are both 0, such that the composition comprises a β—Ga₂O₃ layer disposed on a (010) β—Ga₂O₃ miscut substrate.

19. The composition of claim 1, wherein the substrate comprises β—(AlₓGa₁₋ₓ)₂O₃, such that the composition comprises a β—(AlₓGa₁₋ₓ)₂O₃ layer disposed on a (010) β—(AlₓGa₁₋ₓ)₂O₃ miscut substrate.

20. The composition of claim 1, further comprising a second layer disposed on the first layer opposite the substrate, wherein the second layer comprises β—(Al_{y}Ga_{1-y})₂O₃ where y is from 0 to 1, a doped material or a combination thereof.

21. The composition of claim 20, wherein the composition of the second layer varies.

22. The composition of claim 20, wherein the second layer comprises β—(Al_{y}Ga_{1-y})₂O₃ and the value of y varies across the layer.

23. A method of making the composition of claim 1, the method comprising contacting a first precursor and a second precursor at a first temperature and a first pressure in the presence of the substrate, wherein the first precursor comprises gallium and/or aluminum and the second precursor comprises oxygen, to thereby react the first precursor and the second precursor to deposit the first layer on the substrate.

24.-51. (canceled)

52. A device comprising the composition of claim 1, wherein the device comprises a vertical power device, an optical device, an electronic device, an optoelectronic device, or a combination thereof.

53.-56. (canceled)
